(19) United States
(12) Patent Application Publication
(10) Pub. No.: US 2026/0164950 A1
(43) Pub. Date: Jun. 11, 2026

(54) DISPLAY PANEL, AND ELECTRONIC DEVICE INCLUDING THE SAME

(71) Applicant: Samsung Display Co., LTD., Yongin-si (KR)

(72) Inventor: HYONGDO CHOI, Yongin-si (KR)

(21) Appl. No.: 19/179,556

(22) Filed: Apr. 15, 2025

(30) Foreign Application Priority Data
Apr. 16, 2024 (KR) 10-2024-0050836

(51) Int. Cl. H10K 59/124; H10K 59/80

(52) U.S. Cl. CPC H10K 59/124; H10K 59/873

(57) ABSTRACT

A display panel includes: a base layer; a circuit layer disposed on the base layer and including a transistor; a display element layer disposed on the circuit layer, and including a light-emitting element; and an organic insulation layer disposed between the circuit layer and the display element layer. A plurality of first recess patterns are defined on an upper surface of the organic insulation layer and do not penetrate the organic insulation layer, the light-emitting element includes a first electrode, a second electrode disposed on the first electrode, and a light-emitting layer disposed between the first electrode and the second electrode, and a portion of the first electrode is disposed inside the plurality of first recess patterns.

This U.S. application claims priority to Korean Patent Application No. 10-2024-0050836, filed on Apr. 16, 2024, and all the benefits accruing therefrom under 35 U.S.C. § 119, the content of which in its entirety is herein incorporated by reference.

### BACKGROUND

The present disclosure herein relates to a display panel and a display device including the same, and more particularly, to a display panel with increased light output efficiency and a display device including the same.

Display devices are used in various multimedia apparatuses such as televisions, mobile phones, tablet computers, and game consoles to provide image information to a user. Recently, various types of flexible display devices, which are foldable or bendable, have been developed. Flexible display devices may be deformed variously, for example, folded, rolled, or bent, and thus easy to carry.

Recently, display panels with increased light output efficiency are required for various types of display devices such as curved display devices, rollable display devices and foldable display devices.

### SUMMARY

The present disclosure provides a display panel with improved light output efficiency and a display device including the same.

An embodiment of the invention provides a display panel including: a base layer; a circuit layer disposed on the base layer and including a transistor; a display element layer disposed on the circuit layer, and including a light-emitting element; and an organic insulation layer disposed between the circuit layer and the display element layer. A plurality of first recess patterns are defined on an upper surface of the organic insulation layer and do not penetrate the organic insulation layer, the light-emitting element includes a first electrode, a second electrode disposed on the first electrode, and a light-emitting layer disposed between the first electrode and the second electrode, and a portion of the first electrode is disposed inside the plurality of first recess patterns.

In an embodiment, the upper surface of the organic insulation layer may include a top surface, and an inner surface defining each of the plurality of first recess patterns, and each of the plurality of first recess patterns may be depressed by a first depth in a direction from the top surface to the circuit layer.

In an embodiment, the first depth may be about 0.01 micrometers (μm) to about 0.5 μm.

In an embodiment, the first electrode may include a first portion which is in contact with the top surface, and a second portion which is in contact with the inner surface of each of the plurality of first recess patterns.

In an embodiment, a thickness of the first portion may be substantially the same as a thickness of the second portion.

In an embodiment, the inner surface of each of the plurality of first recess patterns may include a lower surface facing a bottom surface of the organic insulation layer, and a side surface extending from the top surface toward the lower surface.

In an embodiment, the bottom surface of the organic insulation layer may be in contact with the circuit layer, and a first minimum distance between the bottom surface of the organic insulation layer and the top surface may be longer than a second minimum distance between the bottom surface of the organic insulation layer and the lower surface.

In an embodiment, the lower surface and the side surface may form a first angle therebetween, and the first angle may be about 90 degrees to about 150 degrees.

In an embodiment, the base layer may include a light-emitting region corresponding to the light-emitting element and a non-light emitting region adjacent to the light-emitting region, and the plurality of first recess patterns may overlap the light-emitting region.

In an embodiment, the display element layer may further include a pixel-defining film overlapping the non-light emitting region and disposed on the organic insulation layer.

In an embodiment, an opening may be defined in the pixel-defining film, and at least a portion of the first electrode may be exposed by the opening.

In an embodiment, the plurality of first recess patterns may be disposed spaced apart from each other in a first direction, and a distance between adjacent first recess patterns of the plurality of first recess patterns in the first direction may be about 0.1 μm to about 10 μm.

In an embodiment, a first width of each of the plurality of first recess patterns in the first direction may be about 0.1 μm to about 10 μm.

In an embodiment, the light-emitting element may further include a hole transport region disposed between the first electrode and the light-emitting layer, and an electron transport region disposed between the light-emitting layer and the second electrode, and the hole transport region may be directly disposed on the first electrode.

In an embodiment, the hole transport region may include an organic material.

In an embodiment, the display panel may further include an encapsulation layer disposed on the display element layer.

In an embodiment, a plurality of second recess patterns, which correspond to the plurality of first recess patterns, respectively, may be defined on an upper surface of the second electrode, and a portion of the encapsulation layer may fill each of the plurality of second recess patterns.

In an embodiment of the invention, an electronic device includes: a display panel including a light-emitting region and a non-light emitting region adjacent to the light-emitting region, a power supply configured to provide power to the display panel, an optical layer disposed on the display panel, and a window disposed on the optical layer, where the display panel includes: a base layer; a circuit layer disposed on the base layer and including a transistor; a display element layer disposed on the circuit layer, and including a light-emitting element, and an organic insulation layer disposed between the circuit layer and the display element layer, where a plurality of first recess patterns are defined on an upper surface of the organic insulation layer and do not penetrate the organic insulation layer, the light-emitting element includes a first electrode, a second electrode disposed on the first electrode, and a light-emitting layer disposed between the first electrode and the second electrode, and a portion of the first electrode is disposed inside the plurality of first recess patterns.

In an embodiment, the electronic device may further include a sensor layer disposed between the display panel and the optical layer.

In an embodiment, the optical layer may include an organic pattern overlapping the non-light-emitting region and disposed on the display panel, and a refractive layer covering the organic pattern, and a refractive index of the high refractive layer may be higher than a refractive index of the organic pattern.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is an assembled perspective view of a display device according to an embodiment of the invention;

FIG. 1B is an exploded perspective view of a display device according to an embodiment of the invention;

FIG. 2 is a plan view of a display device according to an embodiment of the invention;

FIG. 3 is a cross-sectional view illustrating a portion of a display module according to an embodiment of the invention;

FIG. 4 is a cross-sectional view illustrating a portion of a display panel according to an embodiment of the invention;

FIG. 5 is a cross-sectional view schematically illustrating a light-emitting element according to an embodiment of the invention;

FIG. 6 is a cross-sectional view illustrating a portion of a display panel according to an embodiment of the invention;

FIG. 7 is a plan view illustrating a portion of a light-emitting element according to an embodiment of the invention; and

FIG. 8 is a block diagram illustrating an electronic device according to an embodiment.

### DETAILED DESCRIPTION

In this specification, it will be understood that when an element (or region, layer, portion, etc.) is referred to as being “on”, “connected to” or “coupled to” another element, it can be directly disposed on/connected to/coupled to the other element or intervening elements may be present.

Like reference numerals or symbols refer to like elements throughout the specification. In addition, in terms of drawings, the thickness and the ratio and the dimension of the element are exaggerated for effective description of the technical contents. As used herein, the term “and/or” includes any and all combinations of one or more of the associated listed items.

Terms such as “first” and “second” may be used to describe various components, but the components should not be limited by the terms. These terms are only used for the purpose of distinguishing one component from other components. For example, without departing from the scope of the invention, a first component may be referred to as a second component, and similarly, a second component may be referred to as a first component. Singular expressions include plural expressions unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value. Hereinafter, embodiments of the invention will be described with reference to the accompanying drawings.

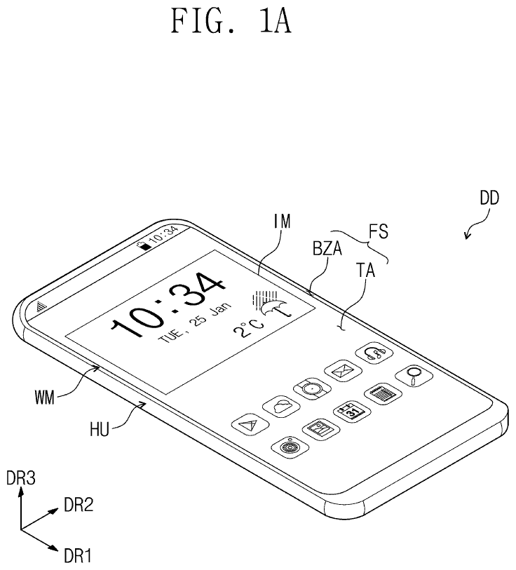

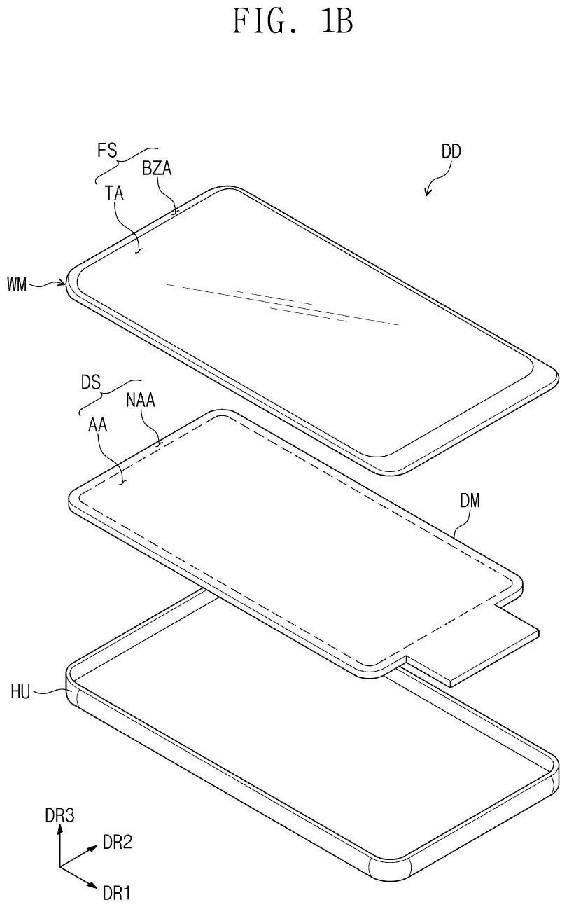

FIG. 1A is an assembled perspective view of a display device according to an embodiment of the invention. FIG. 1B is an exploded perspective view of a display device according to an embodiment of the invention.

Referring to FIGS. 1A and 1B, a display device DD may be activated in response to an electrical signal. The display device DD may display an image IM and sense an external input. The display device DD may include various embodiments. For example, the display device DD may include a tablet PC, a laptop computer, a computer, a smart television, or the like. In this embodiment, the display device DD is exemplarily illustrated as a smart phone.

The display device DD may display the image IM toward a third direction DR3 on a display surface FS that is parallel to each of a first direction DR1 and a second direction DR2. The display surface FS on which the image IM is displayed may correspond to a front surface of the display device DD, and may correspond to a front surface FS of a window WM. Hereinafter, the display surface and front surface of the display device DD and the front surface of the window WM will be denoted as the same reference character “FS”. The image IM may include a static image as well as a dynamic image. In FIG. 1A, a clock and a plurality of icons are illustrated as an example of the image IM.

In this embodiment, a front surface (or upper surface) and a rear surface (or lower surface) of each member are defined on the basis of a direction in which the image IM is displayed. The front surface and the rear surface may be opposed to each other in the third direction DR3, and the normal direction of each of the front surface and the rear surface may be parallel to the third direction DR3. A spaced distance between the front surface and the rear surface in the third direction DR3 may correspond to a thickness of a display panel 100 in the third direction DR3.

Meanwhile, the directions indicated by the first to third directions DR1, DR2, and DR3 may have a relative concept and may thus be changed to other directions. Hereinafter, first to third directions may be the directions respectively indicated by the first to third directions DR1, DR2, and DR3, and may thus be denoted as the same reference numerals or symbols. In addition, in this specification, “on a plane” may mean “when viewed in the third direction DR3” (i.e., plan view).

The display device DD according to an embodiment of the invention may sense a user's input applied from the outside. The user's input may include various types of external inputs such as a part of the user's body, light, heat, or pressure. The user's input may be provided in various forms, and the display device DD may sense the user's input applied to a side surface or the rear surface of the display device DD depending on the structure of the display device DD. The invention is not limited to any one embodiment.

As illustrated in FIG. 1B, the display device DD may include a window WM, a display module DM, and an outer case HU. In this embodiment, the window WM and the outer case HU are coupled to each other to constitute the exterior of the display device DD. In this embodiment, the outer case HU, the display module DM, and the window WM may be stacked sequentially along the third direction DR3.

The window WM may provide a front surface FS of the display device DD. The front surface FS of the window WM may define the front surface of the display device DD as mentioned above. A transmission region TA may be an optically transparent region. For example, the transmission region TA may be a region having visible light transmittance of about 90% or more.

A bezel region BZA may be a region having a relatively lower light transmittance than the transmission region TA. The bezel region BZA defines the shape of the transmission region TA. The bezel region BZA may be adjacent to the transmission region TA, and may surround the transmission region TA.

The bezel region BZA may have a predetermined color. The bezel region BZA may cover a peripheral region NAA of the display module DM, and thus block the peripheral region NAA from being visible to the outside. Meanwhile, this is exemplarily illustrated, and the bezel region BZA may be omitted in the window WM according to an embodiment of the invention.

The window WM may include an optically transparent material. The window WM may include an insulation panel. For example, the window WM may be composed of glass, plastic, or a combination thereof.

The window WM may further include functional layers such as an anti-reflection layer or an anti-fingerprint layer. Although not illustrated, the window WM may further include a bezel pattern overlapping the aforementioned bezel region BZA.

The display module DM may display an image IM and sense an external input. The image IM may be displayed on a front surface DS of the display module DM. The front surface DS of the display module DM may include an active region AA and a peripheral region NAA. The active region AA may be activated in response to an electrical signal.

In this embodiment, the active region AA may be a region in which the image IM is displayed, and also the external input is sensed. The transmission region TA may overlap at least the active region AA. For example, the transmission region TA may overlap a front surface or at least a portion of the active region AA. Accordingly, a user may view the image IM or provide an external input, through the transmission region TA. However, this is exemplarily illustrated, and within the active region AA, the region in which the image IM is displayed may be separated from the region in which the external input is sensed. The invention is not limited to any one embodiment.

The peripheral region NAA may be a region covered by the bezel region BZA. The peripheral region NAA may be adjacent to the active region AA. The peripheral region NAA may surround the active region AA. A driving circuit or driving wires for driving the active region AA may be disposed in the peripheral region NAA.

The display module DM may include a display panel and a sensor layer. The image IM may be displayed substantially on the display panel, and the external input may be sensed substantially by the sensor layer. Since the display module DM includes both the display panel and the sensor layer, displaying the image IM and sensing the external input may be performed simultaneously. This will be described in detail later.

The display device DD according to an embodiment may further include a driving circuit. The driving circuit may include a flexible printed circuit board and a main circuit board. The flexible printed circuit board may be electrically connected to the display module DM. The flexible printed circuit board may connect the display module DM and the main circuit board. However, this is exemplarily illustrated, and the flexible printed circuit board according to the invention may not be connected to the main circuit board. The flexible printed circuit board may be a rigid board.

The flexible printed circuit board may be connected to pads of the display module DM which are disposed in the peripheral region NAA. The flexible printed circuit board may provide, to the display module DM, an electrical signal for driving the display module DM. The electrical signal may be generated from the flexible printed circuit board or may be generated from the main circuit board. The main circuit board may include various driving circuits for driving the display module DM, a connector for power supply, or the like. The main circuit board may be connected to the display module DM through the flexible printed circuit board.

Meanwhile, FIG. 1B exemplarily illustrates that the display module DM is in an unfolded state, but at least a portion of the display module DM may be bent. In this embodiment, a portion of the display module DM may be bent toward a rear surface of the display module DM, and the portion that is bent toward the rear surface may be a portion connected to the main circuit board. Accordingly, the main circuit board may be assembled while overlapping the rear surface of the display module DM.

The outer case HU may be coupled to the window WM to define the exterior of the display device DD. The outer case HU may provide a predetermined inner space. The display module DM may be accommodated in the inner space.

The outer case HU may include a substance having relatively high rigidity. For example, the outer case HU may include glass, plastic, or metal, or may include a plurality of frames and/or plates composed of a combination thereof. The outer case HU may stably protect components of the display device DD, which are accommodated in the inner space, from external impacts.

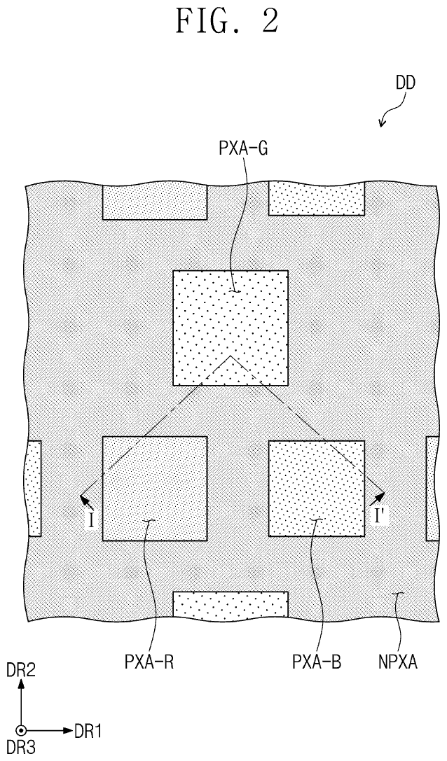

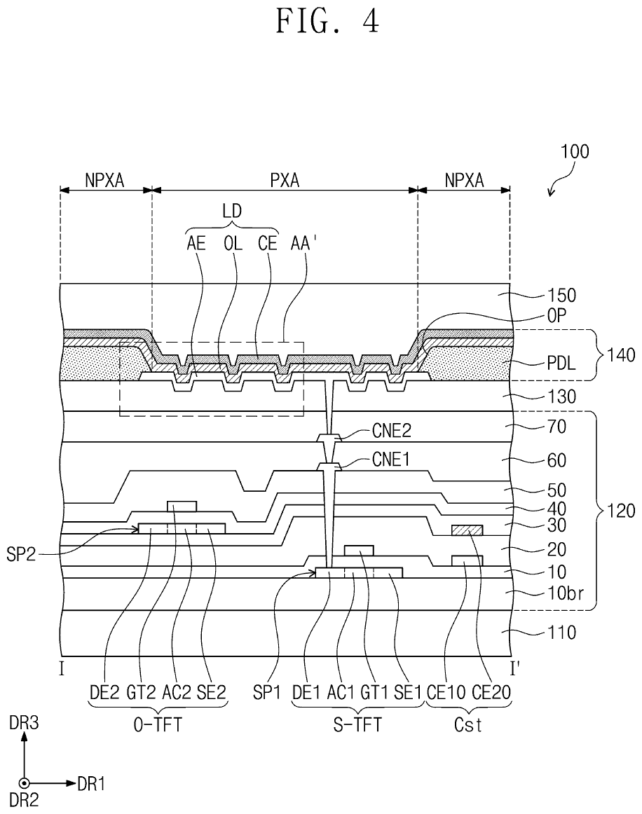

FIG. 2 is a plan view illustrating an enlarged portion of a display device according to an embodiment. As used herein, the plan view is a view in a thickness direction (i.e., third direction DR3) of the display device (e.g., base layer 110. See FIG. 4).

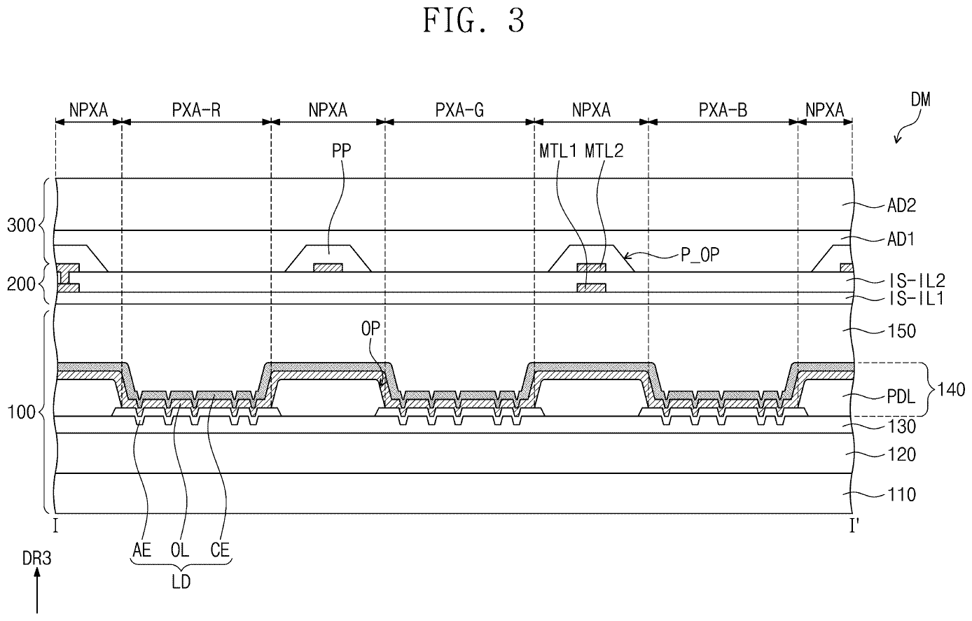

Referring to FIG. 2, a display device DD according to an embodiment may include a plane having three light-emitting regions PXA-R, PXA-G, and PXA-B, and a non-light emitting region NPXA adjacent thereto. In an embodiment of the invention, three types of light-emitting regions PXA-R, PXA-G, and PXA-B illustrated in FIG. 3 may be arranged repeatedly throughout the active region AA (see FIG. 1B).

The non-light emitting region NPXA may be disposed around first to third light-emitting regions PXA-R, PXA-G, and PXA-B. The non-light emitting region NPXA demarcates boundaries of the first to third light-emitting regions PXA-R, PXA-G, and PXA-B. The non-light emitting region NPXA may surround the first to third light-emitting regions PXA-R, PXA-G, and PXA-B. In the non-light emitting region NPXA, a structure, for example, a pixel-defining film PDL (see FIG. 3), etc., for preventing color mixing between the first to third light-emitting regions PXA-R, PXA-G, and PXA-B may be disposed.

FIG. 2 exemplarily illustrates that the first to third light-emitting regions PXA-R, PXA-G, and PXA-B have the same planar shape, and respectively have different planar areas, but an embodiment of the invention is not limited thereto. At least two of the first to third light-emitting regions PXA-R, PXA-G, and PXA-B may have the same area. The areas of the first to third light-emitting regions PXA-R, PXA-G, and PXA-B may be set depending on a color of light output.

FIG. 2 illustrates that the first to third light-emitting regions PXA-R, PXA-G, and PXA-B have rectangular shapes, but an embodiment of the invention is not limited thereto. The first to third light-emitting regions PXA-R, PXA-G, and PXA-B may have, on a plane (i.e., in a plan view), polygonal shapes (including substantially polygonal shapes) of different shapes such as rhombuses or pentagons. In an embodiment, the first to third light-emitting regions PXA-R, PXA-G, and PXA-B, on a plane, may have rectangular shapes (substantially rectangular shapes) with rounded corners.

FIG. 2 exemplarily illustrates that the second light-emitting region PXA-G is disposed in a first row, and the first light-emitting region PXA-R and the third light-emitting region PXA-B are disposed in a second row, but an embodiment of the invention is not limited thereto. The arrangement of the first to third light-emitting regions PXA-R, PXA-G, and PXA-B may be variously modified. For example, the first to third light-emitting regions PXA-R, PXA-G, and PXA-B may be disposed in the same row.

In the display device DD according to an embodiment, illustrated in FIG. 2, three light-emitting regions PXA-R, PXA-G, and PXA-B which emit blue color light, green color light, and red color light are exemplarily illustrated. For example, the display device DD according to an embodiment may include a red-color light-emitting region PXA-R, a green-color light-emitting region PXA-G, and a blue-color light-emitting region PXA-B which are distinguished from each other. In this specification, the red-color light-emitting region PXA-R, the green-color light-emitting region PXA-G, and the blue-color light-emitting region PXA-B may be respectively referred to as the first light-emitting region PXA-R, the second light-emitting region PXA-G, and the third light-emitting region PXA-B.

FIG. 3 is a cross-sectional view of a display module according to an embodiment. FIG. 3 illustrates a cross-section of a display module DM taken along line I-I′ of FIG. 2.

Referring to FIG. 3, the display module DM according to an embodiment may include a display panel 100, a sensor layer 200, and an optical layer 300.

The display panel 100 may be a component that substantially generates an image. The display panel 100 may be a light-emitting display panel, and for example, the display panel 100 may be an organic light-emitting display panel, an inorganic light-emitting display panel, a micro-LED display panel, or a nano-LED display panel.

The display panel 100 may include a base layer 110, a circuit layer 120, an organic insulation layer 130, a display element layer 140, and an encapsulation layer 150.

The base layer 110 may be a member for providing a base surface on which the circuit layer 120 is disposed. The base layer 110 may be a rigid substrate, or a flexible substrate that is bendable, foldable, rollable, etc. The base layer 110 may be a glass substrate, a metal substrate, a polymer substrate, or the like. However, an embodiment of the invention is not limited thereto, and the base layer 110 may be an inorganic layer, an organic layer, or a composite material layer.

The base layer 110 may have a multi-layered structure. For example, the base layer 110 may include a first synthetic resin layer, a multi-or single-layered inorganic layer, and a second synthetic resin layer disposed on the multi-or single-layered inorganic layer. The first and second synthetic resin layers may each include a polyimide-based resin, and are not particularly limited.

The circuit layer 120 may be disposed on the base layer 110. The circuit layer 120 may include an insulation layer, a semiconductor pattern, a conductive pattern, a signal line, and the like (See FIG. 4).

The organic insulation layer 130 may be disposed on the circuit layer 120. The organic insulation layer 130 may include a general-purpose polymer such as benzocyclobutene (“BCB”), polyimide, hexamethyldisiloxane (“HMDSO”), polymethylmethacrylate (“PMMA”), or polystyrene (“PS”), a polymer derivative having a phenol-based group, an acrylate-based polymer, an imide-based polymer, an aryl ether-based polymer, an amide-based polymer, a fluorine-based polymer, a p-xylene-based polymer, a vinyl alcohol-based polymer, a blend thereof, and/or the like.

The display element layer 140 may be disposed on the organic insulation layer 130. The display element layer 140 may include pixel-defining films PDL and a light-emitting element LD disposed between the pixel-defining films PDL.

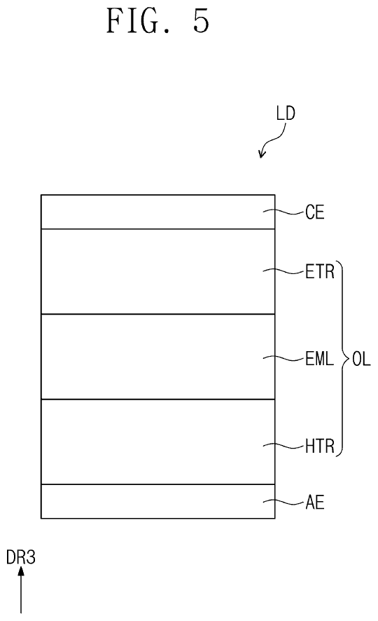

The light-emitting element LD may include an organic light-emitting material, an inorganic light-emitting material, an organic-inorganic light-emitting material, quantum dots, quantum rods, a micro-LED, or a nano-LED. The light-emitting element LD may include a first electrode AE, an organic layer OL, and a second electrode CE. The organic layer OL may include a light-emitting layer EML (see FIG. 5).

Openings OP are defined in the pixel-defining films PDL. The openings OP may expose at least a portion of the first electrode AE. The light-emitting regions PXA-R, PXA-G, and PXA-B may be defined corresponding to the first electrode AE exposed by the corresponding openings OP. The light-emitting regions PXA-R, PXA-G, and PXA-B may overlap the pixel-defining films PDL in a plan view.

FIG. 3 illustrates an embodiment in which the organic layer OL and the second electrode CE are provided as common layers throughout the three light-emitting regions PXA-R, PXA-G, and PXA-B. However, an embodiment of the invention is not limited thereto, and unlike what is illustrated in FIG. 3, in another embodiment, the organic layer OL and/or the second electrode CE may be provided by being patterned inside the openings OP defined in the pixel-defining films PDL. For example, in an embodiment, a hole transport region HTR (see FIG. 5), the light-emitting layer EML (see FIG. 5), and an electron transport region ETR (see FIG. 5), which are included in the organic layer OL, may be provided by being patterned through an inkjet printing method.

The encapsulation layer 150 may be disposed on the display element layer 140. The encapsulation layer 150 may protect the display element layer 140 from moisture, oxygen, and foreign matters such as dust particles. The encapsulation layer 150 may include at least one inorganic layer. The encapsulation layer 150 may include a stacked structure of inorganic layer/organic layer/inorganic layer.

The sensor layer 200 may be disposed on the display panel 100. The sensor layer 200 may sense an external input applied from the outside. The external input may be a user's input. The user's input may include various types of external inputs such as a part of the user's body, light, heat, a pen or pressure.

The sensor layer 200 may be formed on the display panel 100 through a continuous process. In such cases, the sensor layer 200 may be directly disposed on the display panel 100. Here, the wording “directly disposed” may mean that a third component is not disposed between the sensor layer 200 and the display panel 100. That is, an additional adhesive member may not be disposed between the sensor layer 200 and the display panel 100.

The sensor layer 200 may include sensing insulation layers IS-IL1 and IS-IL2 and conductive patterns MTL1 and MTL2. The sensing insulation layers IS-IL1 and IS-IL2 may each include an inorganic material.

A first conductive pattern MTL1 may be disposed on a first sensing insulation layer IS-IL1, and may be covered by a second sensing insulation layer IS-IL2. A second conductive pattern MTL2 may be disposed on the second sensing insulation layer IS-IL2. The second conductive pattern MTL2 may overlap the pixel-defining film PDL in a plan view. Accordingly, the second conductive pattern MTL2 may be spaced apart from the light-emitting regions PXA-R, PXA-G, and PXA-B, and may overlap the non-light emitting region NPXA.

A portion of the second conductive pattern MTL2 may pass through the second sensing insulation layer IS-IL2 and may be connected to the first conductive pattern MTL1. According to an embodiment, the second conductive pattern MTL2 may include mesh lines overlapping the non-light emitting region NPXA. The mesh lines may respectively extend in different diagonal directions with respect to a first direction DR1 and a second direction DR2, and mesh openings corresponding to the openings OP defined in the pixel-defining films PDL may be defined in the mesh lines.

The mesh lines may have a multi-layered structure. For example, the mesh lines may include first to third layers. A coupling force of a first layer to the encapsulation layer 150 may be greater than a coupling force of a second layer. The second layer may have higher conductivity than the first and third layers. The third layer may have a lower external light reflectance than the second layer. The first layer may be titanium, the second layer may be aluminum, and the third layer may be titanium.

However, an embodiment of the invention is not limited thereto, and the second conductive pattern MTL2 having a multi-layered structure may include at least two among transparent conductive layers and metal layers. The second conductive pattern MTL2 having the multi-layered structure may include metal layers containing different metals. The transparent conductive layer may include indium tin oxide (ITO), indium zinc oxide (IZO), zinc oxide (ZnO), indium tin zinc oxide (ITZO), PEDOT, metal nanowires, and graphene. The metal layer may include molybdenum, silver, titanium, copper, aluminum, and an alloy thereof.

The optical layer 300 may be directly disposed on the sensor layer 200. The optical layer 300 may be formed on the sensor layer 200 through a continuous process. The optical layer 300 may control a direction of light incident from the display panel 100, and may improve the front luminance of the display device DD. The optical layer 300 may collect light provided from the display panel 100, or may further spread light generated in some regions of the display panel 100.

The optical layer 300 may include an organic pattern PP, a high refractive layer AD1, and an adhesive layer AD2.

The organic pattern PP may overlap the pixel-defining film PDL (or the non-light emitting region NPXA), on a plane. Accordingly, the organic pattern PP may be spaced apart from the light-emitting regions PXA-R, PXA-G, and PXA-B, and may overlap the non-light emitting region NPXA. The organic pattern PP may cover the second conductive pattern MTL2. That is, the organic pattern PP may be in contact with the second sensing insulation layer IS-IL2 and the second conductive pattern MTL2 overlapping the non-light emitting region NPXA.

A pattern opening P_OP may be defined in the organic pattern PP. The pattern opening P_OP may correspond to the opening OP defined in the pixel-defining film PDL. Accordingly, the pattern openings may correspond to the light-emitting regions PXA-R, PXA-G, and PXA-B in a one-to-one correspondence. An area of the pattern opening P_OP according to an embodiment may be greater than an area of the opening OP.

The organic pattern PP may include an acrylate-based resin, an epoxide-based resin, a siloxane-based resin, a polyimide-based resin, or a mixture thereof. The organic pattern PP may include hollow silica particles. The organic pattern PP may have a refractive index of about 1.50 to about 1.54.

The high refractive layer AD1 may be disposed on the organic pattern PP. The high refractive layer AD1 may cover the second sensing insulation layer IS-IL2 and the organic pattern PP which are exposed by the pattern opening P_OP. The high refractive layer AD1 may be an adhesive layer including a high refractive material. For example, the high refractive layer AD1 may include a base layer having an acrylate-based monomer and a high refractive material included in the base layer. The high refractive material may include at least any one of zirconium oxide, titanium oxide, or zinc oxide. A refractive index of the high refractive layer AD1 according to an embodiment may be higher than the refractive index of the organic pattern PP. In this embodiment, the high refractive layer AD1 may have a refractive index of about 1.55 to about 1.70.

The high refractive layer AD1 may be a transparent adhesive layer including any one among a pressure sensitive adhesive film (“PSA”), an optically clear adhesive film (“OCA”), and an optically clear resin (“OCR”).

The adhesive layer AD2 may be disposed on the high refractive layer AD1. The adhesive layer AD2 may provide a flat surface for any one component which is disposed on the adhesive layer AD2. The adhesive layer AD2 may be a transparent adhesive layer including any one among a pressure sensitive adhesive film (PSA), an optically clear adhesive film (OCA), and an optically clear resin (OCR).

However, a stacked structure of the optical layer 300 according to an embodiment is not limited thereto, and the optical layer 300 may further include one functional layer disposed on the adhesive layer AD2, or may be a component that does not include the adhesive layer AD2. Alternatively, unlike what is illustrated in FIG. 3, the optical layer 300 according to another embodiment may include a high refractive pattern overlapping the pixel-defining film PDL on a plane (i.e., in a plan view), and a low refractive layer covering the high refractive pattern.

Unlike what is illustrated in FIG. 3, in the display module DM according to another embodiment of the invention, the sensor layer 200 may be omitted. In such cases, the optical layer 300 may be directly disposed on the display panel 100. In the display module DM according to another embodiment, the optical layer 300 may be omitted. Alternatively, in the display module DM according to another embodiment, the sensor layer 200 and the optical layer 300 may all be omitted.

Although not illustrated, in an embodiment of the invention, the display device DD may further include an optical functional layer disposed between the optical layer 300 and the sensor layer 200. For example, the optical functional layer may reduce a reflectance for external light incident from the outside of the display device DD. The optical functional layer may include color filters. The color filters may have a predetermined arrangement. For example, the color filters may be arranged in consideration of emission colors of light from pixels included in the display panel 100. In addition, the optical functional layer may further include a black matrix adjacent to the color filters.

FIG. 4 is a cross-sectional view illustrating a portion of a display panel according to an embodiment of the invention. FIG. 4 illustrates a partial cross-section of a display panel 100 with respect to one light-emitting element LD. In FIG. 4, a portion of the display panel 100 is illustrated in detail, focusing on one light-emitting element LD overlapping any one light-emitting region PXA among the light-emitting regions PXA-R, PXA-G, and PXA-B in FIG. 3. FIG. 5 is a cross-sectional view schematically illustrating a light-emitting element according to an embodiment. Hereinafter, components of the display panel 100 in this embodiment will be described in detail with reference to FIGS. 4 and 5.

Referring to FIG. 4, the display panel 100 according to an embodiment may include a base layer 110. The base layer 110 may be a member for providing a base surface on which a circuit layer 120 is disposed. The base layer 110 may be a glass substrate, a metal substrate, a plastic substrate, a silicon substrate, or the like. However, an embodiment of the invention is not limited thereto, and the base layer 110 may be an inorganic layer, an organic layer, or a composite material layer in another embodiment.

A buffer layer 10br may be disposed on the base layer 110. The buffer layer 10br may prevent metal atoms or impurities from being spread from the base layer 110 to a first semiconductor pattern SP1 thereabove. The first semiconductor pattern SP1 may include a channel region AC1 of a silicon transistor S-TFT. The buffer layer 10br may control a heat supply rate during a crystallization process for forming the first semiconductor pattern SP1, and thus make the first semiconductor pattern SP1 formed uniformly.

The first semiconductor pattern SP1 may be disposed on the buffer layer 10br. The first semiconductor pattern SP1 may include a silicon semiconductor. For example, the silicon semiconductor may include amorphous silicon, polycrystalline silicon, single crystal silicon, or the like. For example, the first semiconductor pattern SP1 may include low-temperature polysilicon.

FIG. 4 illustrates only a portion of the first semiconductor pattern SP1 disposed on the buffer layer 10br, and the first semiconductor pattern SP1 may also be disposed in another region. The first semiconductor pattern SP1 may be arranged in accordance with a specific rule across pixels. The first semiconductor pattern SP1 may have different electrical properties depending on whether to be doped or not. The first semiconductor pattern SP1 may have a first region with high conductivity and a second region with low conductivity. The first region may be doped with an N-type dopant or a P-type dopant. A P-type transistor may include a doped region that is doped with the P-type dopant, and an N-type transistor may include a doped region that is doped with the N-type dopant. The second region may be undoped region, or may be a region doped at a lower concentration than the first region.

The conductivity of the first region may be greater than a coupling force of the second region, and the first region may substantially serve as an electrode or a signal line. The second region may substantially correspond to an active region (or channel) of a transistor. That is, a portion of the first semiconductor pattern SP1 may be the active region of the transistor, another portion may be a source or drain of the transistor, and still another portion may be a connection electrode or a connection signal-line.

A source region SE1 (or source), a channel region AC1 (or channel), and a drain region DE1 (or drain) of the silicon transistor S-TFT may be formed from the first semiconductor pattern SP1. The source region SE1 and the drain region DE1 may respectively extend in opposite directions from the channel region AC1, on a cross-section.

Meanwhile, although not illustrated, a back metal layer may be disposed on each of a lower part of the silicon transistor S-TFT and a lower part of an oxide transistor O-TFT. The back metal layer may be disposed overlapping a pixel circuit PC in a plan view, and may block external light from reaching the pixel circuit PC. The back metal layer may be disposed between the base layer 110 and the buffer layer 10br. Alternatively, the back metal layer may be disposed between a second insulation layer 20 and a third insulation layer 30. The back metal layer may include reflective metal. For example, the back metal layer may include silver (Ag), an Ag-containing alloy, molybdenum (Mo), a Mo-containing alloy, aluminum (Al), an Al-containing alloy, aluminum nitride (AIN), tungsten (W), tungsten nitride (WN), copper (Cu), p+-doped amorphous silicon, and the like. The back metal layer may be connected to an electrode or wiring, and may receive a constant voltage or a signal therefrom. According to an embodiment of the invention, the back metal layer may be a floating electrode in a form isolated from other electrodes or wiring. In an embodiment of the invention, an inorganic barrier layer may also be disposed between the base layer 110 and the buffer layer 10br.

A first insulation layer 10 may be disposed on the buffer layer 10br. The first insulation layer 10 may overlap a plurality of pixels in common, and may cover the first semiconductor pattern SP1. The first insulation layer 10 may be an inorganic layer and/or an organic layer, and may have a single- or multi-layered structure. The first insulation layer 10 may include at least one of aluminum oxide, titanium oxide, silicon oxide, silicon nitride, silicon oxynitride, zirconium oxide, or hafnium oxide. In this embodiment, the first insulation layer 10 may be a single-layered silicon oxide layer. An insulation layer of the circuit layer 120 to be described later as well as the first insulation layer 10 may be inorganic layers and/or organic layers, and may have a single- or multi-layered structure. The inorganic layer may include at least one of the aforementioned materials, but is not limited thereto.

A gate GT1 of the silicon transistor S-TFT may be disposed on the first insulation layer 10. The gate GT1 may be a part of a metal pattern. The gate GT1 may overlap the channel region AC1 in a plan view. The gate GT1 may function as a mask in a process of doping the first semiconductor pattern SP1. The gate GT1 may include titanium (Ti), silver (Ag), an Ag-containing alloy, molybdenum (Mo), a Mo-containing alloy, aluminum (Al), an Al-containing alloy, aluminum nitride (AIN), tungsten (W), tungsten nitride (WN), copper (Cu), indium tin oxide (ITO), indium zinc oxide (IZO), etc., but is not particularly limited thereto.

The second insulation layer 20 may be disposed on the first insulation layer 10, and may cover the gate GT1. The third insulation layer 30 may be disposed on the second insulation layer 20. A second electrode CE20 of a storage capacitor Cst may be disposed between the second insulation layer 20 and the third insulation layer 30. In addition, a first electrode CE10 of the storage capacitor Cst may be disposed between the first insulation layer 10 and the second insulation layer 20.

A second semiconductor pattern SP2 may be disposed on the third insulation layer 30. The second semiconductor pattern SP2 may include a channel region AC2 of the oxide transistor O-TFT to be described later. The second semiconductor pattern SP2 may include an oxide semiconductor. The second semiconductor pattern SP2 may include a transparent conductive oxide (TCO) such as indium tin oxide (ITO), indium zinc oxide (IZO), indium gallium zinc oxide (IGZO), zinc oxide (ZnO), or indium oxide (In₂O₃).

The oxide semiconductor may include a plurality of regions which are distinguished depending on whether the transparent conductive oxide has been reduced or not. A region in which the transparent conductive oxide is reduced (hereinafter, a reduced region) may have greater conductivity than a region in which the transparent conductive oxide is not reduced (hereinafter, a non-reduced region). The reduced region may substantially serve as a source/drain of a transistor or a signal line. The non-reduced region may substantially correspond to a semiconductor region (or active region or channel) of a transistor. That is, one region of the second semiconductor pattern SP2 may be the semiconductor region of the transistor, and another region may be a source region/drain region of the transistor, and still another region may be a signal transmission region.

A source region SE2 (or source), a channel region AC2 (or channel), and a drain region DE2 (or drain) of the oxide transistor O-TFT may be formed from the second semiconductor pattern SP2. The source region SE2 and the drain region DE2 may respectively extend in opposite directions from the channel region AC2, on a cross-section.

A fourth insulation layer 40 may be disposed on the third insulation layer 30. The fourth insulation layer 40 may overlap a plurality of pixels in common, and may cover the second semiconductor pattern SP2. Although not illustrated, the fourth insulation layer 40 may be provided in the form of an insulation pattern which overlaps a gate GT2 of the oxide transistor O-TFT in a plan view and exposes the source region SE2 and the drain region DE2 of the oxide transistor O-TFT.

The gate GT2 of the oxide transistor O-TFT may be disposed on the fourth insulation layer 40. The gate GT2 of the oxide transistor O-TFT may be a part of a metal pattern. The gate GT2 of the oxide transistor O-TFT may overlap the channel region AC2.

A fifth insulation layer 50 may be disposed on the fourth insulation layer 40, and may cover the gate GT2. A first connection electrode CNE1 may be disposed on the fifth insulation layer 50. The first connection electrode CNE1 may be connected to the drain region DE1 of the silicon transistor S-TFT via a contact hole which passes through the first to fifth insulation layers 10, 20, 30, 40, and 50.

A sixth insulation layer 60 may be disposed on the fifth insulation layer 50. A second connection electrode CNE2 may be disposed on the sixth insulation layer 60. The second connection electrode CNE2 may be connected to the first connection electrode CNE1 via a contact hole which passes through the sixth insulation layer 60. A seventh insulation layer 70 may be disposed on the sixth insulation layer 60, and may cover the second connection electrode CNE2.

An organic insulation layer 130 may be disposed on the seventh insulation layer 70. An upper surface of the organic insulation layer 130 may have a recessed shape. The organic insulation layer 130 will be described in detail later.

The sixth insulation layer 60, the seventh insulation layer 70, and the organic insulation layer 130 may be organic layers. For example, the sixth insulation layer 60, the seventh insulation layer 70, and the organic insulation layer 130 may each include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylate-based polymer, an imide-based polymer, an aryl ether-based polymer, an amide-based polymer, a fluorine-based polymer, a p-xylene-based polymer, a vinyl alcohol-based polymer, a blend thereof, or the like.

A light-emitting element LD may include a first electrode AE, a second electrode CE, and an organic layer OL disposed between the first electrode AE and the second electrode CE. The first electrode AE may be a cathode or an anode, but an embodiment of the invention is not limited thereto. For example, when the first electrode AE is an anode, the second electrode CE may be a cathode, and when the first electrode AE is a cathode, the second electrode CE may be an anode.

The first electrode AE of the light-emitting element LD may be disposed on the organic insulation layer 130. The second electrode CE of the light-emitting element LD may be disposed on the organic layer OL. The first electrode AE and the second electrode CE of the light-emitting element LD may each be a (semi-) transmissive electrode or a reflective electrode. According to an embodiment of the invention, the first electrode AE and the second electrode CE of the light-emitting element LD may each include a reflection layer which is formed of Ag, Mg, Cu, Al, Pt, Pd, Au, Ni, Nd, Ir, Cr, Li, Ca, LiF/Ca, LiF/Al, Mo, Ti, Yb, W, a compound or mixture thereof (for example, AgMg, AgYb, or MgYb), or the like, and a transparent or translucent electrode layer that is formed on the reflection layer. The transparent or translucent electrode layer may include at least one selected from groups including indium tin oxide (ITO), indium zinc oxide (IZO), indium gallium zinc oxide (IGZO), zinc oxide (ZnO) or indium oxide (In₂O₃), and aluminum-doped zinc oxide (AZO). For example, the first electrode AE of the light-emitting element LD may include a stacked structure of ITO/Ag/ITO.

A pixel-defining film PDL may be disposed on the organic insulation layer 130. The entire pixel-defining film PDL may include the same material, and may be formed through the same process. The pixel-defining film PDL may have a property of absorbing light, and for example, the pixel-defining film PDL may have a black color. The pixel-defining film PDL may include a black coloring agent. The black coloring agent may include black dye, and black pigment. The black coloring agent may include carbon black, metal such as chrome, or an oxide thereof. The pixel-defining film PDL may correspond to a light-blocking pattern having a light-blocking property.

The pixel-defining film PDL may cover a portion of the first electrode AE of the light-emitting element LD. For example, an opening OP, which exposes a portion of the first electrode AE of the light-emitting element LD, may be defined in the pixel-defining film PDL. The pixel-defining film PDL may increase a distance between the edge of the first electrode AE and the second electrode CE in the light-emitting element LD. Accordingly, the pixel-defining film PDL may serve to prevent an arc, etc., from occurring at the edge of the first electrode AE.

Referring to FIGS. 4 and 5, the light-emitting element LD according to an embodiment may include the first electrode AE, a hole transport region HTR, a light-emitting layer EML, an electron transport region ETR, and the second electrode CE which are sequentially stacked.

The hole transport region HTR may be provided on the first electrode AE. The hole transport region HTR may be directly disposed on the first electrode AE. The hole transport region HTR may include an organic material. The hole transport region HTR may include a hole transport layer, and may further include a hole injection layer. The light-emitting layer EML may be provided on the hole transport region HTR, and the electron transport region ETR may be provided on the light-emitting layer EML. The electron transport region ETR may include an electron transport layer, and may further include an electron injection layer. The light-emitting layer EML and the electron transport region ETR may be layers including an organic material or an inorganic material.

Referring to FIG. 4, an encapsulation layer 150 may be disposed on a display element layer 140. The encapsulation layer 150 may include a first inorganic encapsulation film, an organic encapsulation film and a second inorganic encapsulation film which are sequentially stacked, but the layers that constitute the encapsulation layer 150 are not limited thereto.

The first and second inorganic encapsulation films may protect the display element layer 140 from moisture and oxygen, and the organic encapsulation film may protect the display element layer 140 from foreign matters such as dust particles. The first and second inorganic encapsulation films may include a silicon nitride layer, a silicon oxynitride layer, a silicon oxide layer, a titanium oxide layer, an aluminum oxide layer, or the like. The organic encapsulation film may include an acrylate-based organic layer, and is not limited thereto.

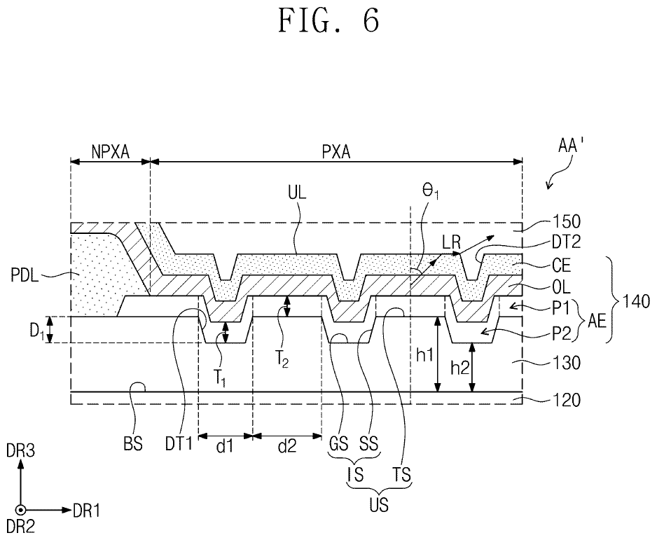

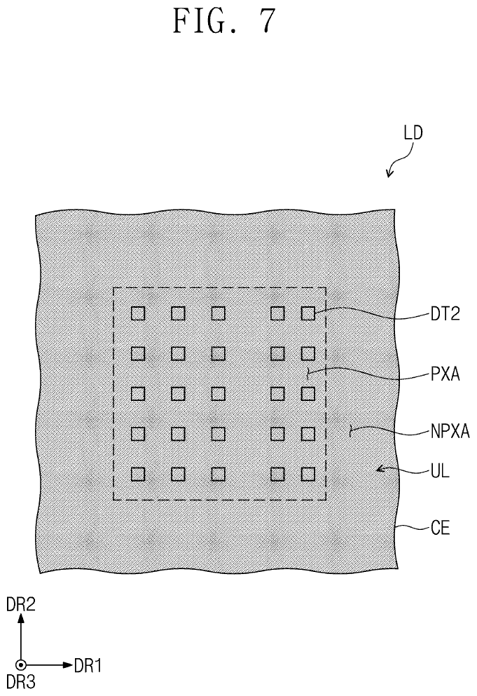

FIG. 6 is a cross-sectional view illustrating a portion of a display panel according to an embodiment of the invention. In FIG. 6, a cross-section of a portion corresponding to the AA′ region illustrated in FIG. 4 is enlarged and illustrated in more detail. FIG. 7 is a plan view illustrating a portion of a light-emitting element according to an embodiment of the invention. FIG. 7 illustrates a plan view of one light-emitting element LD illustrated in FIG. 4.

Referring to FIG. 6, in the display panel 100 (see FIG. 4) according to an embodiment, an organic insulation layer 130 may be disposed on a circuit layer 120, a display element layer 140 may be disposed on the organic insulation layer 130, and an encapsulation layer 150 may be disposed on the display element layer 140.

A bottom surface BS of the organic insulation layer 130 may be in contact with the circuit layer 120, and the organic insulation layer 130 may be directly disposed on the circuit layer 120. The bottom surface BS of the organic insulation layer 130 may be disposed on the seventh insulation layer 70 (see FIG. 4) of the circuit layer 120. The organic insulation layer 130 may substantially cover an upper part of the circuit layer 120.

An upper surface US of the organic insulation layer 130 may include a top surface TS facing the bottom surface BS of the organic insulation layer 130 in a third direction DR3. The top surface TS may have a first distance h1 (i.e., height) from the bottom surface BS of the organic insulation layer 130 in the third direction DR3. The top surface TS may be flat and parallel to a plane defined by the first direction DR1 and the second direction DR2.

A plurality of first recess patterns DT1 may be defined on the upper surface US of the organic insulation layer 130. The first recess pattern DT1 may have a shape that is recessed in a direction of getting closer to the circuit layer 120 from the top surface TS. The first recess pattern DT1 may have a shape that is recessed from the top surface TS by a first depth D₁ in a direction opposite to the third direction DR3. Meanwhile, in this specification, the first depth D₁ may mean the minimum distance between the top surface TS and a lower surface GS to be described later in the third direction DR3. The first depth D₁ may be about 0.01 μm to about 0.5 μm. For example, the first depth D₁ may be about 0.05 μm to about 0.3 μm. The organic insulation layer 130 may be provided by forming one flat insulation layer on the circuit layer 120, and then forming the first recess pattern DT1 on an upper surface of the one flat insulation layer. The first recess pattern DT1 may be formed through development and photolithography of the one flat insulation layer.

The upper surface US of the organic insulation layer 130 may include an inner surface IS defining the first recess pattern DT1. The inner surface IS defining the first recess pattern DT1 may include a lower surface GS facing the bottom surface BS of the organic insulation layer 130 in the third direction DR3, and a side surface SS extending from the top surface TS toward the lower surface GS. The lower surface GS may be flat and parallel to the plane defined by the first direction DR1 and the second direction DR2. The lower surface GS may have a second minimum distance h2 from the bottom surface BS of the organic insulation layer 130 in the third direction DR3, and the second minimum distance h2 may be shorter than the first distance h1. The lower surface GS and the side surface SS may form a first angle therebetween, and the first angle may be about 90 degrees to about 150 degrees. However, an embodiment of the invention is not limited thereto, and the first recess pattern DT1 may have various shapes as long as the shapes have structures recessed from the top surface TS.

The plurality of first recess patterns DT1 may be disposed spaced apart from each other on a plane. The plurality of first recess patterns DT1 may be disposed spaced apart from each other in a first direction DR1. A spaced distance d2 between two adjacent first recess patterns DT1 in the first direction DR1 may be about 0.1 μm to about 10 μm. For example, the spaced distance d2 between the two adjacent first recess patterns DT1 in the first direction DR1 may be about 1 μm to about 5 μm. The first recess pattern DT1 may have a first width d1 in the first direction DR1. The first width d1 may be about 0.1 μm to about 10 μm. For example, the first width d1 may be about 1 μm to about 5 μm. However, the first width d1 and the spaced distance d2 between the two adjacent first recess patterns DT1 in the first direction DR1 are not limited to the aforementioned respective numerical ranges, and may have various values.

The plurality of first recess patterns DT1 may overlap a light-emitting region PXA on a plane. The plurality of first recess patterns DT1 may overlap the light-emitting region PXA, and may not overlap a non-light emitting region NPXA, on a plane (i.e., in a plan view).

The display element layer 140 may be disposed on the organic insulation layer 130, and may include a light-emitting element LD. The light-emitting element LD may include a first electrode AE disposed on the organic insulation layer 130, an organic layer OL disposed on the first electrode AE, and a second electrode CE disposed on the organic layer OL.

A portion of the first electrode AE may be disposed inside the first recess pattern DT1. The first electrode AE may be directly disposed on the organic insulation layer 130. The first electrode AE may be in contact with the upper surface US of the organic insulation layer 130.

The first electrode AE may include a first portion P1 disposed on the top surface TS (or overlapping the top surface TS in a plan view), and a second portion P2 disposed inside the first recess pattern DT1 (or overlapping the first recess pattern DT1 in a plan view). The first portion P1 may be in contact with the top surface TS, and the second portion P2 may be in contact with the inner surface IS defining the first recess pattern DT1. A thickness T₁ of the first portion P1 may be substantially the same as a thickness T₂ of the second portion P2 in the third direction DR3. Meanwhile, in this specification, the wording “substantially the same” may include not only a case in which the thicknesses, etc., of components are physically and completely identical, but also a case in which there is a difference as much as a tolerance range (e.g., within ±10%, 5% or 2% of the stated value) that occurs during the process, despite the same design. That is, the thickness of the first electrode AE may be substantially uniform in a cross-sectional view.

The organic layer OL may be disposed on the first electrode AE, and the organic layer OL may include the hole transport region HTR (see FIG. 5), the light-emitting layer EML (see FIG. 5), and the electron transport region ETR (see FIG. 5) which are sequentially stacked. The organic layer OL may be directly disposed on the first electrode AE. The hole transport region HTR (see FIG. 5) may be directly disposed on the first electrode AE. The organic layer OL may be directly disposed on the first portion P1 of the first electrode AE, and may be directly disposed on the second portion P2 of the first electrode AE. An upper surface of the organic layer OL may follow steps formed on an upper surface of the first electrode AE which is disposed under the organic layer.

Referring to FIGS. 6 and 7, the second electrode CE may be disposed on the organic layer OL, and a plurality of second recess patterns DT2 may be defined on an upper surface UL of the second electrode CE. In a region overlapping the first recess pattern DT1, the second recess pattern DT2 that is recessed by a certain depth in a direction opposite to the third direction DR3 may be defined on the upper surface UL of the second electrode CE. The plurality of second recess patterns DT2 may have recessed shapes respectively corresponding to the plurality of first recess patterns DT1.

The plurality of second recess patterns DT2 may be disposed spaced apart from each other in the first direction DR1 and a second direction DR2. The plurality of second recess patterns DT2 may overlap the light-emitting region PXA on a plane. The plurality of second recess patterns DT2 may overlap the light-emitting region PXA, and may not overlap the non-light emitting region NPXA, on a plane (i.e., in a plan view). Meanwhile, in FIG. 7, it is illustrated for convenience that 25 second recess patterns DT2 in 5 rows and 5 columns are defined in one light-emitting region PXA, but the number and arrangement of the plurality of second recess patterns DT2 are not limited thereto. In addition, in FIG. 7, it is illustrated for convenience that a planar shape of the second recess pattern DT2 is a square shape, but the shape of the second recess pattern DT2 is not limited thereto. The second recess pattern DT2 may have various shapes.

The encapsulation layer 150 may be disposed on the display element layer 140, and the encapsulation layer 150 may be disposed on the second electrode CE. A portion of the encapsulation layer 150 may be disposed inside the plurality of second recess patterns DT2. The portion of the encapsulation layer 150 may fill each of the plurality of second recess patterns DT2.

Although not illustrated, the display element layer 140 according to an embodiment may further include a capping layer. The light-emitting element LD may further include the capping layer disposed on the second electrode CE, and an upper surface of the capping layer may have an unevenness. The upper surface of the capping layer may have a recessed pattern in a region overlapping the first recess pattern DT1 in a plan view, and the encapsulation layer 150 may fill the inside of the recessed pattern on the upper surface of the capping layer.

The upper surface UL of the second electrode CE may substantially represent the uppermost surface of the light-emitting element LD, and in this specification, the upper surface UL of the second electrode CE may be referred to as “the upper surface UL of the light-emitting element LD”. The upper surface UL of the light-emitting element LD includes the plurality of second recess patterns DT2, and thus may substantially have an unevenness. The unevenness may be substantially defined on the upper surface UL of the light-emitting element LD since the light-emitting element LD is stacked with a uniform thickness not only on the top surface TS of the organic insulation layer 130 but also on the inner surface IS defining the first recess pattern DT1 of the organic insulation layer 130. Since the upper surface UL of the light-emitting element LD includes the unevenness, the light-emitting efficiency of the display panel 100 (see FIG. 4) according to an embodiment of the invention may be increased. Even when an angle θ₁ of light LR emitted from the light-emitting element LD (e.g., the organic layer OL) with respect to a normal direction (i.e., third direction DR3) of the upper surface UL of the light-emitting element LD is about 30 degrees or more, the light-output amount of the display panel 100 (see FIG. 4) according to embodiments may be improved (i.e., increased) by optical path changes (from total reflection on the upper surface UL to passing through the side surface of the second recess patterns DT2 as shown in FIG. 6) caused by the unevenness (i.e., the second recess patterns DT2) of the upper surface UL of the light-emitting element LD, while in a comparative example without the recessed patterns, the corresponding light is reflected on the upper surface such that the light cannot pass through the upper surface. Accordingly, in the display panel according to an embodiment of the invention, the output amount of light generated from the light-emitting element may increase, and light-emitting efficiency may be improved. Since the display device according to an embodiment of the invention includes the display panel with improved optical properties, the display device with improved reliability may be provided.

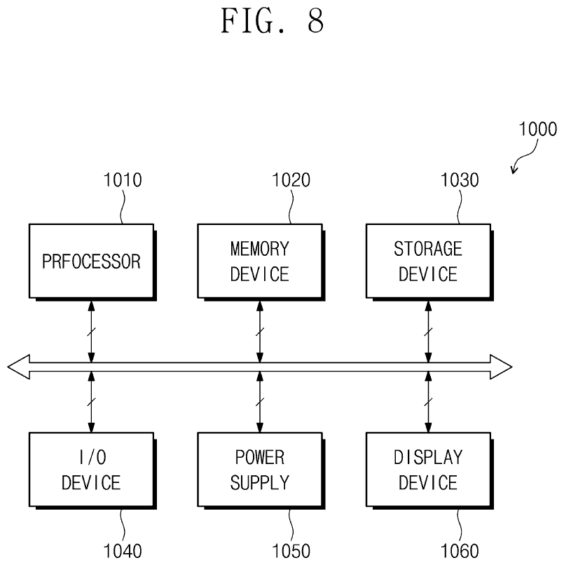

FIG. 8 is a block diagram illustrating an electronic device according to an embodiment.

Referring to FIG. 8, in an embodiment, an electronic device 1000 may include a processor 1010, a memory device 1020, a storage device 1030, an input/output (“I/O”) device 1040, a power supply 1050, and a display device 1060. Here, the display device 1060 may correspond to the display device DD of FIGS. 1A to 2. The electronic device 1000 may further include a plurality of ports for communicating with a video card, a sound card, a memory card, a universal serial bus (“USB”) device, or the like. In an embodiment, the electronic device 1000 may be implemented as a television. In another embodiment, the electronic device 1000 may be implemented as a smart phone. However, embodiments are not limited thereto, in another embodiment, the electronic device 1000 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device 1000. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device 1000. The power supply 1050 may provide power to the display device 1060. The display device 1060 may be coupled to other components via the buses or other communication links. In an embodiment, the display device 1060 may be included in the I/O device 1040.

According to the invention, since a display panel includes an uneven upper surface of a light-emitting element, light-emitting efficiency may be improved. Accordingly, the reliability of a display device including the display panel may be improved.

In the above, description has been made with reference to embodiments, but those skilled in the art or those of ordinary skill in the relevant technical field may understand that various modifications and changes may be made to the invention within the scope not departing from the spirit and the technology scope of the invention described in the claims to be described later. Therefore, the technical scope of the invention is not limited to the contents described in the detailed description of the specification, but should be determined by the claims.

What is claimed is:

1. A display panel comprising:
a base layer;
a circuit layer disposed on the base layer and including a transistor;
a display element layer disposed on the circuit layer, and including a light-emitting element; and
an organic insulation layer disposed between the circuit layer and the display element layer,
wherein a plurality of first recess patterns are defined on an upper surface of the organic insulation layer,
the light-emitting element includes a first electrode, a second electrode disposed on the first electrode, and a light-emitting layer disposed between the first electrode and the second electrode, and
a portion of the first electrode is disposed inside the plurality of first recess patterns.

2. The display panel of claim 1, wherein the upper surface of the organic insulation layer comprises a top surface, and an inner surface defining each of the plurality of first recess patterns, and
each of the plurality of first recess patterns is depressed by a depth in a direction from the top surface to the circuit layer.

3. The display panel of claim 2, wherein the depth is about 0.01 micrometers (μm) to about 0.5 μm.

4. The display panel of claim 2, wherein the first electrode comprises a first portion which is in contact with the top surface, and a second portion which is in contact with the inner surface of each of the plurality of first recess patterns.

5. The display panel of claim 4, wherein a thickness of the first portion is substantially the same as a thickness of the second portion.

6. The display panel of claim 2, wherein the inner surface of each of the plurality of first recess patterns comprises a lower surface facing a bottom surface of the organic insulation layer, and a side surface extending from the top surface toward the lower surface.

7. The display panel of claim 6, wherein the bottom surface of the organic insulation layer is in contact with the circuit layer, and
a first distance between the bottom surface of the organic insulation layer and the top surface is longer than a second distance between the bottom surface of the organic insulation layer and the lower surface.

8. The display panel of claim 6, wherein the lower surface and the side surface form a first angle therebetween, and
the first angle is about 90 degrees to about 150 degrees.

9. The display panel of claim 1, wherein the base layer comprises a light-emitting region corresponding to the light-emitting element and a non-light emitting region adjacent to the light-emitting region, and
the plurality of first recess patterns overlap the light-emitting region.

10. The display panel of claim 9, wherein the display element layer further comprises a pixel-defining film overlapping the non-light emitting region and disposed on the organic insulation layer.

11. The display panel of claim 10, wherein an opening is defined in the pixel-defining film, and at least a portion of the first electrode is exposed by the opening.

12. The display panel of claim 1, wherein the plurality of first recess patterns are disposed spaced apart from each other in a predetermined direction, and
a distance between adjacent first recess patterns of the plurality of first recess patterns in the predetermined direction is about 0.1 μm to about 10 μm.

13. The display panel of claim 12, wherein a width of each of the plurality of first recess patterns in the predetermined direction is about 0.1 μm to about 10 μm.

14. The display panel of claim 1, wherein the light-emitting element further comprises a hole transport region disposed between the first electrode and the light-emitting layer, and an electron transport region disposed between the light-emitting layer and the second electrode, and
the hole transport region is directly disposed on the first electrode.

15. The display panel of claim 14, wherein the hole transport region comprises an organic material.

16. The display panel of claim 1, further comprising an encapsulation layer disposed on the display element layer.

17. The display panel of claim 16, wherein a plurality of second recess patterns, which correspond to the plurality of first recess patterns, respectively, are defined on an upper surface of the second electrode, and
a portion of the encapsulation layer fills each of the plurality of second recess patterns.

18. An electronic device comprising:
a display panel including a light-emitting region and a non-light emitting region adjacent to the light-emitting region;
a power supply configured to provide power to the display panel;
an optical layer disposed on the display panel; and
a window disposed on the optical layer,
wherein the display panel includes
a base layer,
a circuit layer disposed on the base layer and including a transistor,
a display element layer disposed on the circuit layer, and including a light-emitting element, and
an organic insulation layer disposed between the circuit layer and the display element layer,
wherein a plurality of first recess patterns are defined on an upper surface of the organic insulation layer,
the light-emitting element includes a first electrode, a second electrode disposed on the first electrode, and a light-emitting layer disposed between the first electrode and the second electrode, and
a portion of the first electrode is disposed inside the plurality of first recess patterns.

19. The electronic device of claim 18, further comprising a sensor layer disposed between the display panel and the optical layer.

20. The electronic device of claim 18, wherein the optical layer comprises an organic pattern overlapping the non-light emitting region and disposed on the display panel, and a refractive layer covering the organic pattern,
wherein a refractive index of the high refractive layer is higher than a refractive index of the organic pattern.
